(19) United States
(12) Patent Application Publication
(10) Pub. No.: US 2019/0075644 A1
(43) Pub. Date: Mar. 7, 2019

(54) PLASMA PROCESSING APPARATUS

(71) Applicant: TOKYO ELECTRON LIMITED, Tokyo (JP)

(72) Inventors: Taro IKEDA, Yamanashi (JP); Tomohito KOMATSU, Yamanashi (JP); Jun NAKAGOMI, Yamanashi (JP)

(21) Appl. No.: 16/124,065

(22) Filed: Sep. 6, 2018

(30) Foreign Application Priority Data
Sep. 7, 2017 (JP) 2017-172147

(51) Int. Cl. H05H 1/46; C23C 16/511; H01J 37/32

(52) U.S. Cl. CPC H05H 1/46; C23C 16/511; H05H 2001/4615; H01J 37/3244; H01J 37/32477; H01J 37/32192

(57) ABSTRACT

A plasma processing apparatus, for converting a gas into plasma by using microwaves microwaves and processing a target object in a processing chamber, includes a microwave introducing surface and a plurality of gas injection holes. Microwaves from a microwave introducing unit are introduced through microwave introducing surface and surface waves of the microwaves propagate on the microwave introducing surface. The gas injection holes are arranged at predetermined intervals within a predetermined range from a boundary line between the microwave introducing surface and a surface of the processing chamber that is adjacent to the microwave introducing surface.

### CROSS-REFERENCE TO RELATED APPLICATIONS

This application claims priority to Japanese Patent Application No. 2017-172147, filed on Sep. 7, 2017, the entire contents of which are incorporated herein by reference.

### FIELD OF THE INVENTION

The present disclosure relates to a plasma processing apparatus.

### BACKGROUND OF THE INVENTION

In a microwave plasma processing apparatus, microwaves introduced from a microwave introducing unit propagate as surface waves along a microwave introducing surface of a processing chamber. For example, when microwaves are introduced from a ceiling wall of the processing chamber, the ceiling wall is the microwave introducing surface, and the surface waves of the microwaves propagate along the surface of the ceiling wall.

A processing gas supplied to the processing chamber is converted into plasma by the surface waves of the microwaves, and a predetermined process is performed on a wafer loaded into the processing chamber by the plasma. The processing gas is supplied into the processing chamber through, e.g., a plurality of gas holes formed on the ceiling wall or a sidewall of the processing chamber (see, e.g., Japanese Patent Application Publication Nos. 2005-196994, 2008-251674, and 2016-15496).

An end portion of the microwave introducing surface is at an angle of 90° with a surface of the sidewall of the processing chamber. A stepped portion or a joint of parts in the processing chamber is formed on the surface of the ceiling wall or the sidewall. At the corner, the joint and the stepped portion, the electric field of the surface waves of the microwaves concentrates and abnormal discharge may occur.

### SUMMARY OF THE INVENTION

In view of the above, the present disclosure provides a technique of preventing abnormal discharge caused by surface waves of microwaves.

In accordance with an aspect, there is provided a plasma processing apparatus for converting a gas into plasma by using microwaves microwaves and processing a target object in a processing chamber. The plasma processing apparatus includes a microwave introducing surface and a plurality of gas injection holes. Microwaves from a microwave introducing unit are introduced through microwave introducing surface and surface waves of the microwaves propagate on the microwave introducing surface. The gas injection holes are arranged at predetermined intervals within a predetermined range from a boundary line between the microwave introducing surface and a surface of the processing chamber that is adjacent to the microwave introducing surface.

### BRIEF DESCRIPTION OF THE DRAWINGS

The objects and features of the present disclosure will become apparent from the following description of embodiments, given in conjunction with the accompanying drawings, in which:

FIG. 1 shows an example of a microwave plasma processing apparatus according to an embodiment;

FIG. 2 shows an exemplary arrangement of gas injection holes on a surface of a ceiling wall according to an embodiment;

FIG. 3 explains a reflection of surface waves of microwaves in a gas injection hole according to an embodiment;

FIGS. 4A and 4B show measurement results of masking and the electric field of gas injection holes according to an embodiment;

FIGS. 5A to 5D show exemplary modifications of gas injection holes according to an embodiment.

### DETAILED DESCRIPTION OF THE EMBODIMENTS

Hereinafter, embodiments will be described with reference to the accompanying drawings. Like reference numerals will be given to substantially like parts throughout this specification and the drawings, and redundant description thereof will be omitted.

(Microwave Plasma Processing Apparatus)

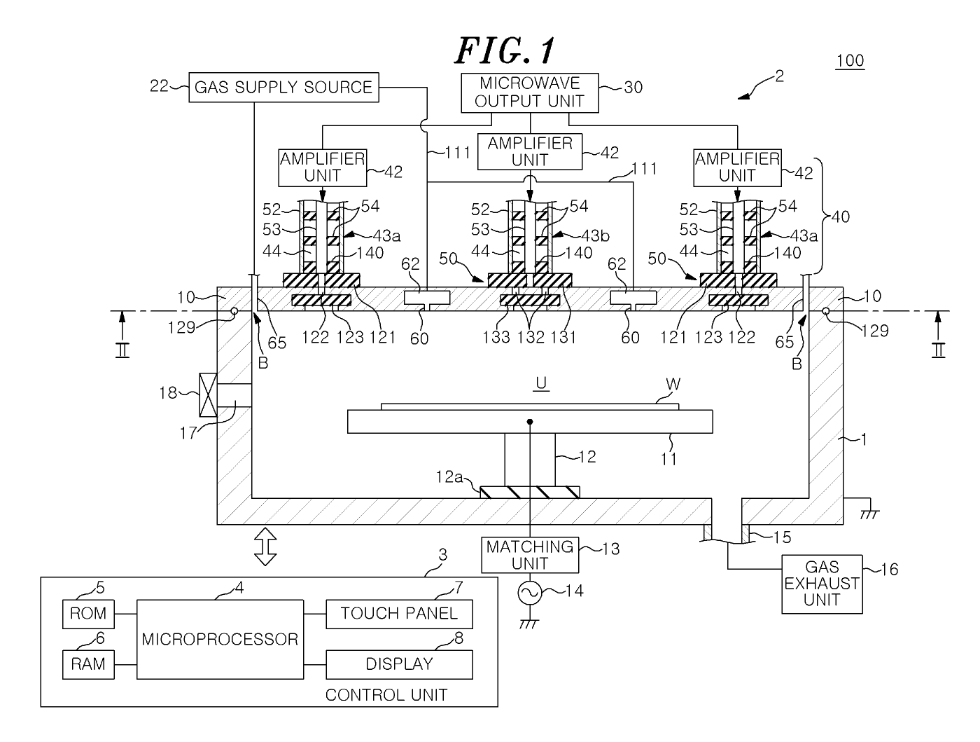

FIG. 1 shows an example of a cross sectional view of a microwave plasma processing apparatus 100 according to an embodiment. The microwave plasma processing apparatus 100 includes a processing chamber 1 for accommodating a wafer W therein. The microwave plasma processing apparatus 100 is an example of a plasma processing apparatus for performing predetermined plasma processing on a semiconductor wafer W thereinafter, referred to as “wafer W”) by surface wave plasma generated on a surface of the processing chamber 1 by microwaves. The predetermined plasma processing may be, e.g., etching or film formation.

The processing chamber 1 is an airtight container having a substantially cylindrical shape and made of a metal such as aluminum, stainless steel, or the like. The processing chamber 1 is grounded. A lid 10 is a ceiling plate forming a ceiling wall of the processing chamber 1. A support ring 129 is provided on a contact surface between the processing chamber 1 and the lid 10. The processing chamber 1 is airtightly sealed. The lid 10 is made of a metal.

A microwave plasma source 2 includes a microwave output unit 30, a microwave transmission unit 40, and a microwave radiation member 50. The microwave output unit 30 distributes and outputs microwaves to a plurality of channels.

The microwave transmission unit 40 transmits the microwaves outputted from the microwave output unit 30. The microwave transmission unit 40 includes peripheral microwave introducing mechanisms 43a and a central microwave introducing mechanism 43b having a function of introducing the microwave outputted from an amplifier unit 42 to the microwave radiation member 50 and a function of matching an impedance.

In the microwave radiation member 50, six dielectric layers 123 corresponding to six peripheral microwave introducing mechanisms 43a are arranged at equal intervals in a circumferential direction in the lid 10. A lower surface of the dielectric layer 123 is exposed in a circular shape to the inside of the processing chamber 1. One dielectric layer 133 corresponding to the central microwave introducing mechanism 43b is provided at the center of the lid 10. A lower surface of the dielectric layer 133 is exposed in a circular shape to the inside of the processing chamber 1.

In each of the peripheral microwave introducing mechanisms 43a and the central microwave introducing mechanism 43b, a cylindrical outer conductor 52 and a rod-shaped inner conductor 53 inserted therein are coaxially arranged. A microwave transmission path 44, to which microwave power is supplied and through which microwaves propagate toward the microwave radiation member 50, is formed between the outer conductor 52 and the inner conductor 53.

Each of the peripheral microwave introducing mechanisms 43a and the central microwave introducing mechanism 43b is provided with slugs 54 and an impedance control member 140 provided at a leading end thereof. An impedance of a load (plasma) in the processing chamber 1 is matched with a characteristic impedance of a microwave power supply in the microwave output unit 30 by moving the slugs 54. The impedance control member 140 is made of a dielectric material and controls an impedance of the microwave transmission path 44 by a relative dielectric constant thereof.

The microwave radiation member 50 is provided at the lid 10. The microwaves outputted from the microwave output unit 30 and transmitted through the microwave transmission unit 40 are radiated into the processing chamber 1 from the microwave radiation member 50.

The microwave radiation member 50 has a dielectric ceiling plate 121 or 131, slots 122 or 132, and a dielectric layer 123 or 133. The dielectric ceiling plate 121 is provided on the lid 10 to correspond to each of the peripheral microwave introducing mechanisms 43a and the dielectric ceiling plate 131 is provided on the lid 10 to correspond to the central microwave introducing mechanism 43b. The dielectric ceiling plates 121 and 131 are disc-shaped dielectric members that transmit microwaves. The dielectric ceiling plates 121 and 131 have a relative dielectric constant greater than that of vacuum. The dielectric ceiling plates 121 and 131 may be made of a ceramic such as quartz, alumina (Al₂O₃) or the like, a fluorine-based resin such as polytetrafluoroethylene or the like, a polyimide-based resin, or the like. The dielectric ceiling plates 121 and 131 are made of a material whose relative dielectric constant is greater than that of a vacuum. Accordingly, the size of an antenna having the slots 122 or 132 can be reduced by making the wavelength of the microwave passing through the dielectric ceiling plate 121 or 131 shorter than the wavelength of the microwave propagating in the vacuum.

Under the dielectric ceiling plates 121 and 131, the dielectric layers 123 and 133 are fitted into the openings of the lid 10 with the slots 122 or 132 formed in the lid 10 interposed between the dielectric ceiling plates 121 or 131 and the dielectric layers 123 or 133, respectively. The dielectric layers 123 and 133 serve as dielectric windows for uniformly generating surface wave plasma of the microwave on the surface of the ceiling wall. In other words, the microwave radiation member 50 including the dielectric layers 123 and 133 is an example of a microwave introducing unit for introducing microwaves. Similarly to the dielectric ceiling plates 121 and 131, the dielectric layers 123 and 133 may be made of, e.g., ceramic such as quartz, alumina (Al₂O₃) or the like, a fluorine-based resin such as polytetrafluoroethylene, a polyimide-based resin, or the like.

The number of peripheral microwave introducing mechanisms 43a and the number of central microwave introducing mechanisms 43b are not limited to those in the present embodiment. For example, only one central microwave introducing mechanism 43b may be provided without providing peripheral microwave introducing mechanisms 43a. Alternatively, one or more peripheral microwave introducing mechanisms 43a may be provided.

A gas inlet 62 of a shower structure is formed at a metal portion of the lid 10, which is made of aluminum or the like. A gas supply source 22 is connected to the gas inlet 62 through a gas supply line 111. A gas is supplied from the gas supply source 22 into the processing chamber 1 through the gas supply line 111 and a plurality of gas supply holes 60 of the gas inlet 62. The gas inlet 62 is an example of a gas shower head for supplying a gas through the plurality of gas supply holes 60 formed in the ceiling wall of the processing chamber 1. The gas may be a gas for plasma generation, e.g., Ar gas or the like, or a gas to be decomposed by high energy, e.g., O₂ gas, N₂ gas or the like.

In the present embodiment, a plurality of gas injection holes 65 penetrating through the lid 10 is formed in contact with a boundary line between the surface (ceiling surface) of the ceiling wall of the processing chamber 1 and the side surface of the processing chamber 1. An inert gas such as Ar gas, He gas or the like is injected from the plurality of gas injection holes 65. The injected inert gas flows in the processing chamber 1 along the side surface thereof.

The surface of the ceiling wall of the processing chamber 1, i.e., the lower surface of the lid 10, is an example of a microwave introducing surface. The surface of the sidewall that is in contact with the surface of the ceiling wall is an example of a surface of the processing chamber 1 that is adjacent to the microwave introducing surface.

A mounting table 11 for mounting the wafer W thereon is provided in the processing chamber 1. The mounting table 11 is supported by a tubular support member 12 provided at the center of a bottom portion of the processing chamber 1 through an insulating member 12a. The mounting table 11 and the support member 12 may be made of a metal such as aluminum having an alumite-treated (anodically oxidized) surface or the like or an insulating member (ceramic or the like) having therein an electrode for high frequency. The mounting table 11 may be provided with an electrostatic chuck for attracting and holding the wafer W, a temperature control unit, a gas flow path for supplying a heat transfer gas to the backside of the wafer W, and the like.

A high frequency bias power supply 14 is electrically connected to the mounting table 11 via a matching unit 13. By supplying high frequency power from the high frequency bias power supply 14 to the mounting table 11, ions in the plasma are attracted to the wafer W. The high frequency bias power supply 14 may not be provided depending on the characteristics of the plasma processing.

A gas exhaust line 15 is connected to the bottom portion of the processing chamber 1, and a gas exhaust unit 16 including a vacuum pump is connected to the gas exhaust line 15. When the gas exhaust unit 16 is driven, the inside of the processing chamber 1 is exhausted. Accordingly, a pressure in the processing chamber 1 is rapidly decreased to a predetermined vacuum level. Provided on a sidewall of the processing chamber 1 are a loading/unloading port 17 for loading/unloading the wafer W and a gate valve 18 for opening/closing the loading/unloading port 17.

The respective components of the microwave plasma processing apparatus 100 are controlled by a control unit 3. The control unit 3 includes a microprocessor 4, ROM (Read Only Memory) 5, and RAM (Random Access Memory) 6. The ROM 5 and the RAM 6 store therein a process sequence and a process recipe that is a control parameter of the microwave plasma processing apparatus 100. The microprocessor 4 controls the respective components of the microwave plasma processing apparatus 100 based on the process sequence and the process recipe. The control unit 3 includes a touch panel 7 and a display 8 and allows for the input and display of results or the like when performing predetermined controls based on the process sequence and the process recipe.

When plasma processing is performed in the microwave plasma processing apparatus 100 configured as described above, first, the wafer W held on a transfer arm is loaded into the processing chamber 1 through the opened gate valve 18 and the loading/unloading port 17. The gate valve 18 is closed after the wafer W is loaded. When the wafer W reaches a position above the mounting table 11, the wafer W is transferred from the transfer arm to pusher pins and then mounted on the mounting table 11 as the pusher pins are lowered. A pressure in the processing chamber 1 is maintained at a predetermined vacuum level by the gas exhaust unit 16. A gas is introduced in a shower shape into the processing chamber 1 from the gas inlet 62. The microwaves radiated from the microwave radiation member 50 through the peripheral microwave introducing mechanisms 43a and the central microwave introducing mechanism 43b propagate on the surface of the ceiling wall. The gas is decomposed by an electric field of the surface waves of the microwaves, and the wafer W is subjected to plasma processing by the surface wave plasma generated near the ceiling surface on the processing chamber 1 side. Hereinafter, a space between the ceiling wall of the processing chamber 1 and the mounting table 11 is referred to as a plasma processing space U.

(Configuration and Arrangement of Gas Injection Holes)

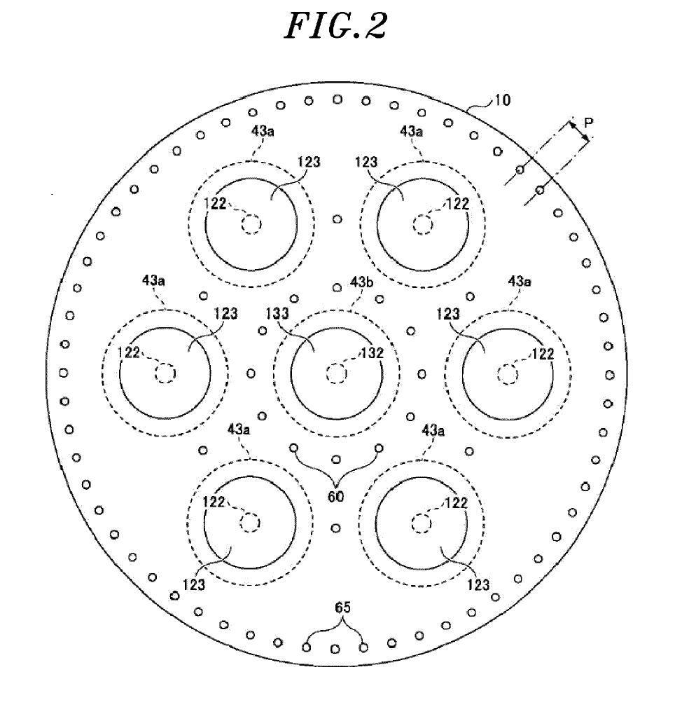

Next, an example of a configuration and arrangement of the gas injection holes 65 according to an embodiment will be described with reference to FIG. 2. FIG. 2 is a cross sectional view taken along line II-II in FIG. 1. As shown in FIG. 2, microwaves are radiated from the dielectric layers 123 and 133 of the microwave introducing unit.

The gas injection holes 65 are arranged at predetermined intervals in the circumferential direction and in contact with a boundary line B (see FIG. 1) between the ceiling surface and the surface (side surface) of the processing chamber 1 (adjacent to the ceiling surface) to surround the dielectric layers 123 and 133 of the microwave introducing unit. Therefore, the inert gas injected through the gas injection holes 65 flows in a circular shape along the side surface of the processing chamber 1. Accordingly, the gas does not stay near the boundary line B of the processing apparatus 1, and peeling due to the gas hardly occurs. As a result, the generation of particles can be prevented.

The interval P between the gas injection holes 65 in the circumferential direction is smaller than or equal to ¼ of the wavelength λ of the surface waves of the microwaves in the plasma. The wavelength λ of the surface waves of the microwaves in the plasma is about ⅓ of the wavelength λ₀ of the microwaves in the vacuum. Since the wavelength λ₀ used in the microwave plasma processing is approximately 120 to 480 mm, the wavelength λ of the surface waves of the microwaves in the plasma is approximately 40 to 160 mm. Therefore, the interval P between the gas injection holes 65 is 10 to 0 mm, which is ¼ of the wavelength λ of the surface waves of the microwaves in the plasma.

With this configuration, in the present embodiment, the gas injection holes 65 are provided at the outer side of the microwave introducing unit. As a consequence, the propagation of the surface waves of the microwaves directly below the gas injection holes 65 can be blocked by the inert gas injected from the gas injection holes 65.

By arranging the injection holes 65 at an interval that is sufficiently smaller than the wavelength λ of the surface waves of the microwaves, e.g., at an interval smaller than or equal to ¼ of the wavelength λ, when the inert gas flows along the side surface from the gas injection holes 65, the gas directly below the gas injection holes 65 functions as a wall when viewed from the surface waves of the microwaves and, thus, the surface waves are reflected by the gas injection holes 65. Accordingly, it is possible to prevent the surface waves of the microwaves from propagating outward beyond the gas injection holes 65 arranged in the circumferential direction.

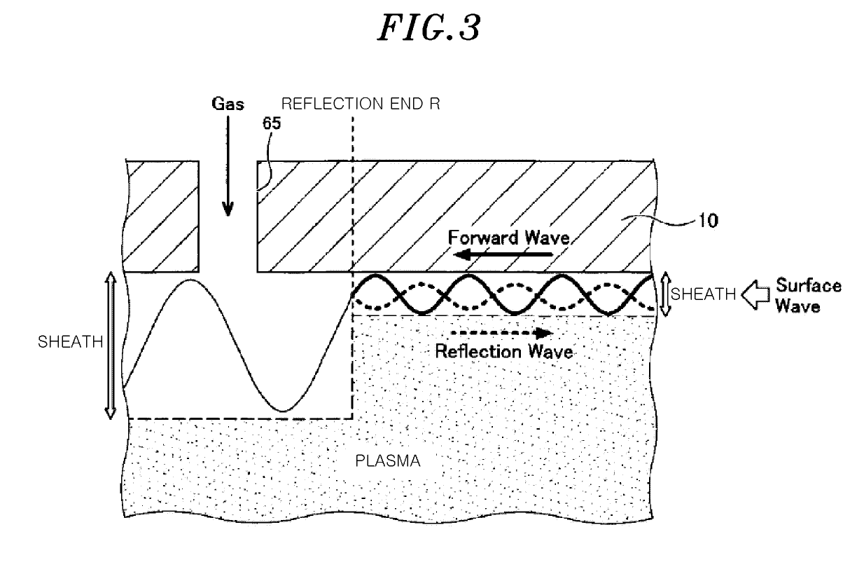

The above will be described in more detail with reference to FIG. 3. FIG. 3 is a conceptual diagram for explaining a reflection state of the surface waves of microwaves in the gas injection holes 65 of the present embodiment. When the inert gas is injected from the gas injection holes 65, the plasma density directly below the gas injection holes 65 becomes lower, and the sheath directly below the gas injection holes 65 becomes thicker than the sheath below the ceiling surface. Therefore, the impedance changes directly below the gas injection holes 65. Accordingly, when viewed from the surface waves of the microwaves, the gas directly below the gas injection holes 65 functions as a wall, and the surface waves of the microwaves are reflected at a reflection end R directly below the gas injection holes 65.

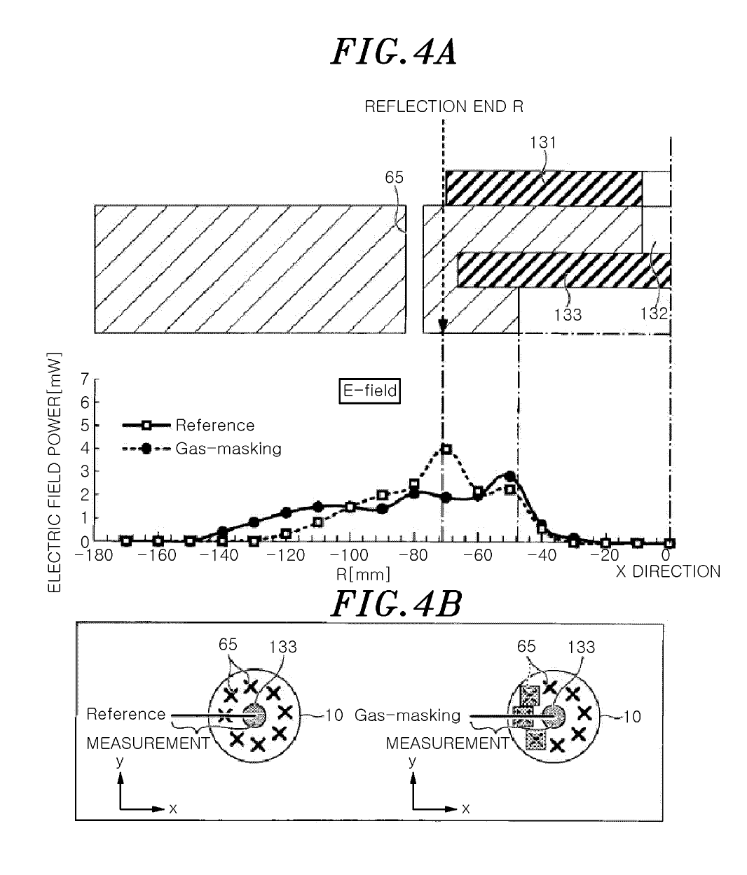

FIGS. 4A and 4B show measurements of masking and the electric field of the gas injection holes 65 of the present embodiment. In the examples of the reference and gas masking, as shown in FIG. 4B, the dielectric layer 123 and the slots 132 connected to the peripheral microwave introducing mechanisms 43b among the microwave introducing units of FIG. 2 are not provided, and the microwaves are introduced from the dielectric layer 133 through the slots 132 connected to the central microwave introducing mechanism 43a. Further, the inert gas is supplied through the gas injection holes 65 arranged around the dielectric layer 133. In the reference, the inert gas is introduced through all the gas injection holes 65 arranged circumferentially around the dielectric layer 133. On the other hand, in gas masking, three left gas injection holes 65 located in the measurement direction among the gas injection holes 65 arranged around the dielectric layer 133 are masked by tapes. Therefore, in the example of gas masking, the inert gas is supplied through the gas injection holes 65 other than the three left gas injection holes 65.

The right end portion of the graph of FIG. 4A indicates the position of the central axis of the dielectric layer 133. The graph of FIG. 4A shows measurement results of the intensity of the electric field by the surface waves of the microwaves at the positions separated from the central axis of the dielectric layer 133 by R mm in the minus direction of the X-axis (X direction.)

In the reference of FIG. 4A, the intensity of the electric field is highest at the reflection end R directly below the gas injection holes 65. This indicates that when the inert gas is injected through the gas injection holes 65, the sheath directly below the gas injection holes 65 becomes thicker than the sheath below the other ceiling surface and, thus, the impedance changes directly below the gas injection holes 65 and the surface waves of the microwaves are reflected at the reflection end R. In other words, the position where the intensity of the electric field becomes highest is the position where the thickness of the sheath changes and the surface waves of the microwaves are reflected.

However, the surface waves of the microwaves are not totally reflected at the reflection end R and partially propagate through the portion directly below the gas injection holes 65, and FIG. 3 shows that the surface waves of the microwaves are reflected at the reflection end R and partially propagate through the portion directly below the gas injection holes 65.

Referring back to FIGS. 4A and 4B, when the gas masking is performed, the reflection end. R is not shown, unlike in the case of the reference. This is because the inert gas is not introduced through the three left gas injection holes 65 and, thus, the sheath directly below the gas injection holes 65 has the same thickness as that of the sheath below the ceiling surface and the impedance does not change. Accordingly, the surface waves of the microwaves are not reflected directly below the gas injection holes 65.

From the above, in the present embodiment, the gas injection holes 65 are arranged in a circumferential direction at intervals of ¼ of the wavelength λ of the surface waves of the microwaves in the plasma, while being in contact with the boundary line B between the ceiling surface and the side surface of the processing chamber 1 that is adjacent to the ceiling surface. Therefore, the propagation of the surface waves can be hindered by attenuating the surface waves of the microwaves propagating from the ceiling surface to the side surface by the gas injection holes 65. Accordingly, it is possible to prevent abnormal discharge from occurring at the corner portion of the boundary line B of the processing chamber 1, the stepped portion, the joint of the parts in the processing chamber 1, and the like.

The diameter of the gas injection holes 65 is set within a range of 0.1 mm to 1 mm. A flow velocity of the inert gas injected through the gas injection holes 65 is preferably 10 m/s or more. If the flow velocity of the gas is slower than 10 m/s, it is difficult to make the sheath directly below the gas injection holes 65 thicker, and the reflection of the surface waves of the microwaves by the impedance change hardly occurs. The flow velocity rate of the inert gas introduced from the gas injection holes 65 may be 100 m/s or less.

The microwaves propagate through the dielectric member. Therefore, it is preferable to coat the aluminum ceiling surface and the aluminum side surface of the processing chamber 1 with an insulating film. For example, an insulating material of yttria (Y₂O₃) or alumina (Al₂O₃) is thermally sprayed on the aluminum ceiling surface and the aluminum side surface of the processing chamber 1, which makes the propagation of the surface waves of the microwaves through the ceiling surface and the side surface of the processing chamber 1 easier. Accordingly, the surface waves of the microwaves easily propagate up to the position of the gas injection holes 65, and the propagation of the surface waves of the microwaves directly below the gas injection holes 65 can be blocked while promoting the generation of plasma by the electric field of the surface waves of the microwaves. As a result, the propagation of the surface waves of the microwaves can be controlled, and the occurrence of abnormal discharge can be suppressed.

(Modification of Gas Injection Holes)

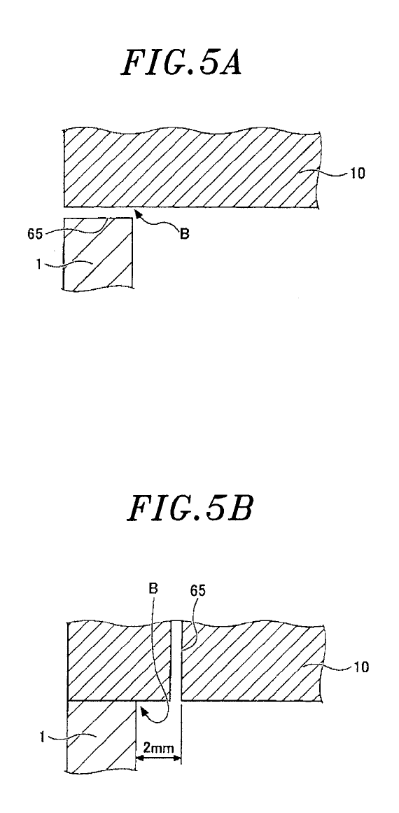

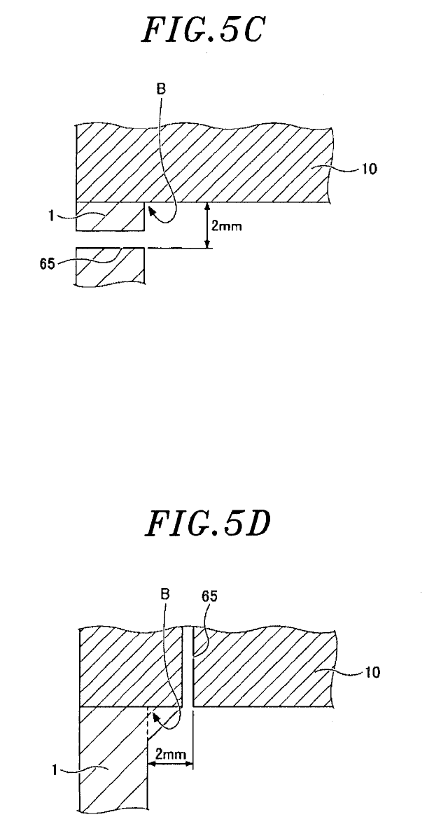

Next, modifications of the gas injection holes 65 will be described with reference to FIGS. 5A to 5D. FIGS. 5A to 5D show exemplary modifications of the gas injection holes 65 of the present embodiment. In the example shown in FIG. 5A, the gas injection holes 65 penetrate through the sidewall of the processing chamber 1 while being in contact with the boundary line B between the ceiling surface and the side surface. In this case as well, the gas injection holes 65 are arranged on the sidewall of the processing chamber 1 at the interval P in the circumferential direction while being in contact with the boundary line B. When the inert gas is injected through the gas injection holes 65, the sheath directly below the gas injection holes 65 becomes thicker than that of the sheath below the other ceiling surface, and the impedance changes greatly. Accordingly, the propagation of the surface waves of the microwaves along the ceiling surface can be blocked. As a result, the propagation of the surface waves of the microwaves can be controlled, and the occurrence of abnormal discharge can be suppressed.

Accordingly, the inert gas injected through the gas injection holes 65 flows along the ceiling surface of the processing chamber 1 without staying at the boundary line B and its vicinity. Therefore, peeling due to the gas hardly occurs, and the generation of particles can be prevented.

In the examples shown in FIGS. 5B and 5C, the gas injection holes 65 are disposed on the ceiling surface or the side surface within 2 mm from the boundary line B between the ceiling surface and the side surface. In the example shown in FIG. 5B, the gas injection holes 65 penetrate through the ceiling wall within 2 mm from the boundary line B, and in the example shown in FIG. 5C, the gas injection holes 65 penetrate through the sidewall within 2 mm from the boundary line B.

If the positions of the gas injection holes 65, either on the ceiling surface or the side surface of the processing chamber 1, are too away from the boundary line B, the gas stays in the vicinity of the boundary line B between the ceiling surface and the side surface. Accordingly, peeling due to the gas is likely to occur, and particles may be generated.

In the examples shown in FIGS. 5B and 5C, the gas injection holes 65 are formed on the ceiling surface or the side surface within 2 mm from the boundary line B between the ceiling surface and the side surface. By arranging the gas injection holes 65 at a predetermined interval near the boundary line B, it is difficult for the gas to stay, and the generation of particles can be prevented.

The arrangement of the gas injection holes 65 within 2 mm from the boundary line B is related to skin depth. The phenomenon in which a current is concentrated on a surface of a conductive layer as the frequency of a high frequency power is increased is referred to as skin effect. The depth through which the current flows is referred to as skin depth.

The skin depth 5 is calculated by the following equation (1).

δ(m)≈c/ωpe Eq. (1)

where c (m/sec) represents the speed of light, ωpe (1/sec) represents electron plasma frequency, ω represents angular frequency (rad/sec) and ωp represents plasma frequency (1/sec). The plasma frequency ωp is approximately equal to the electron plasma frequency ape.

When the speed of light c and the electron plasma frequency cape are substituted into Eq. (1), the skin depth of about 2 mm is obtained in the microwave processing apparatus 100 of the present embodiment. Therefore, when the positions of the gas injection holes 65 are within 2 mm from the boundary line B, the propagation of the surface waves of the microwaves are blocked by the gas injection holes 65, and the effect of attenuating the electric field of the surface waves is improved. Accordingly, it is possible to prevent the occurrence of abnormal discharge at the corner portion of the boundary line B, and the like.

When the gas injection holes 65 are not in contact with the boundary line B as shown in FIG. 5B, the outer ceiling surface or the side surface located outward of the gas injection holes 65 may be inclined in a tapered shape as shown in FIG. 5D. For example, the outer ceiling surface or the side surface of the gas injection holes 65 may be inclined in a bowl shape. When the gas injection holes 65 are formed at the sidewall without being in contact with the boundary line B as shown in FIG. 5C, the outer ceiling surface or the side surface located outward of the gas injection holes 65 may be inclined in a straight line or in a curved shape. By inclining the outer ceiling surface or the side surface located outward of the gas injection holes 65 in a straight line or in a curved shape, it is possible to prevent the gas from staying.

While the embodiment of the plasma processing apparatus has been described, the plasma processing apparatus of the present disclosure is not limited to the above-described embodiment, and various modifications and improvements can be made within the scope of the present disclosure. The contents described in the above embodiments can be combined without contradicting each other.

The plasma processing apparatus of the present disclosure may be applied to a radial line slot antenna.

In this specification, the semiconductor wafer W has been described as an example of the substrate. However, the substrate is not limited thereto, and may also be various substrates for use in LCD (Liquid Crystal Display) and FPD (Flat Panel Display), a CD substrate, a printed board, or the like.

While the present disclosure has been shown and described with respect to the embodiments, it will be understood by those skilled in the art that various changes and modifications may be made without departing from the scope of the present disclosure as defined in the following claims.

What is claimed is:

1. A plasma processing apparatus for converting a gas into plasma by using microwaves microwaves and processing a target object in a processing chamber, the apparatus comprising:
a microwave introducing surface through which microwaves from a microwave introducing unit are introduced and on which surface waves of the microwaves propagate; and
a plurality of gas injection holes arranged at predetermined intervals within a predetermined range from a boundary line between the microwave introducing surface and a surface of the processing chamber that is adjacent to the microwave introducing surface.

2. The plasma processing apparatus of claim 1, wherein the gas injection holes surround the microwave introducing unit.

3. The plasma processing apparatus of claim 1, wherein the predetermined range from the boundary line is within 2 mm from the boundary line.

4. The plasma processing apparatus of claim 1, wherein the microwave introducing surface is a surface of a ceiling wall of the processing chamber;
the surface of the processing chamber that is adjacent to the microwave introducing surface is a surface of a sidewall of the processing chamber; and
the gas injection holes penetrate through the ceiling wall or the sidewall within 2 mm from the boundary line.

5. The plasma processing apparatus of claim 4, wherein the gas injection holes penetrate through the ceiling wall or the sidewall while being in contact with the boundary line.

6. The plasma processing apparatus of claim 1, wherein the predetermined interval is smaller than or equal to ¼ of a wavelength λ of the surface waves of the microwaves in the plasma.

7. The plasma processing method of claim 1, wherein the gas injection holes have a diameter ranging from 0.1 mm to 1 mm.

8. The plasma processing apparatus of claim 1, wherein a flow velocity of a gas introduced through the gas injection holes is 10 m/s or more.

9. The plasma processing apparatus of claim 8, wherein the flow velocity of the gas introduced through the gas injection holes is 100 m/s or less.

10. The plasma processing apparatus of claim 1, wherein the gas introduced through the gas injection holes is an inert gas.

11. The plasma processing apparatus of claim 1, wherein an insulating film is coated on the microwave introducing surface.

12. The plasma processing apparatus of claim 1, wherein the surface waves of the microwaves propagating along the microwave introducing surface are reflected by the gas introduced through the gas injection holes.

13. The plasma processing apparatus of claim 1, wherein when the gas injection holes are not in contact with the boundary line, the microwave introducing surface or the surface of the processing chamber that is adjacent to the microwave introducing surface, located outward of the gas injection holes, is inclined in a straight line or in a curved shape.
